(19) United States
(12) Patent Application Publication
(10) Pub. No.: US 2025/0087605 A1
(43) Pub. Date: Mar. 13, 2025

(54) ELECTRONIC DEVICE

(71) Applicant: STMicroelectronics International N.V., Geneva (CH)

(72) Inventors: Antoine Le Ravallec, Saint-Martin-d'Heres (FR); David Gaidioz, Grenoble (FR); Christophe Arricastres, Grenoble (FR)

(21) Appl. No.: 18/784,674

(22) Filed: Jul. 25, 2024

(30) Foreign Application Priority Data
Sep. 8, 2023 (FR) 2309456

(51) Int. Cl. H01L 23/66; H01L 23/00; H01L 23/522; H01L 23/528; H01L 25/065

(52) U.S. Cl. CPC H01L 23/66; H01L 23/5227; H01L 23/528; H01L 24/08; H01L 24/80; H01L 25/0657; H01L 2223/6677; H01L 2224/08145; H01L 2224/80895; H01L 2224/80896; H01L 2924/19011

(57) ABSTRACT

The present description concerns a device adapted to transmitting and receiving signals with a same antenna, comprising first, second, and third windings, the first and second windings being coupled so as to transmit the signals to be transmitted by the antenna, the first and third windings being coupled so as to transmit the signals received by the antenna, the device comprising first and second chips, the first chip comprising the antenna and the first winding, and the second chip comprising a winding from among the second and third windings, the first and second chips being bonded to each other by molecular bonding.

### CROSS-REFERENCE TO RELATED APPLICATIONS

This application claims the priority benefit of French Patent Application No. 2309456, filed on Sep. 8, 2023, entitled “Dispositif électronique”, which is hereby incorporated by reference to the maximum extent allowable by law.

### TECHNICAL FIELD

The present disclosure relates generally to electronic devices, and, in particular embodiments, transceiver devices.

### BACKGROUND

In the field of wireless communication, there exists a plurality of operating modes allowing a two-way communication between two elements capable of transmitting and of receiving signals.

The duplex or “full duplex” mode is an operating mode where the two circuits can simultaneously send signals. Thus, it is possible to transmit and to receive signals at the same time.

The time division duplex mode is an operating mode where the data transmission and reception occur on a same frequency band, the signals being transmitted successively.

The frequency division duplex mode is an operating mode where the data transmission and reception are simultaneously performed on two different frequency bands. In other words, the frequency of the signal carrier is different according to the transmission direction.

The different operating modes face various issues. An issue is the isolation between the reception portion and the transmission portion.

### SUMMARY

An embodiment overcomes all or part of the disadvantages of known electronic transceiver devices.

An embodiment provides a device adapted to transmitting and receiving signals with a same antenna, comprising first, second, and third windings, the first and second windings being coupled so as to transmit the signals to be transmitted by the antenna, the first and third windings being coupled so as to transmit the signals received by the antenna, the device comprising first and second chips, the first chip comprising the antenna and the first winding, and the second chip comprising one winding from among the second and third windings, the first and second chips being bonded to each other by molecular bonding.

According to an embodiment, the first winding is coupled between the antenna and a node of application of a reference voltage, the second winding is coupled between two terminals of a first circuit configured to generate a signal to be transmitted, the third winding being coupled between two terminals of a second circuit configured to process a received signal.

According to an embodiment, each first or second chip comprises a semiconductor substrate and an interconnection network comprising a stack of insulating layers comprising conductive tracks and conductive vias, each interconnection network comprising a first layer, the first layer of each interconnection network being the most distant from the substrate of said chip, the first and second chips being bonded to each other by the first layers of each interconnection network.

According to an embodiment, the first winding comprises a first conductive track in a second layer of the interconnection network of the first chip, the first track being separated from the second chip only by insulating material.

According to an embodiment, the second winding comprises a second conductive track in a third layer of the interconnection network of the second chip, the second track being separated from the first chip only by insulating material.

According to an embodiment, the third winding comprises a third conductive track in a fourth layer of the interconnection network of the first chip, the third track being separated from the first track by insulating material, the third track being located between the first track and the substrate of the first chip.

According to an embodiment, the third winding comprises a third conductive track in a fifth layer of the interconnection network of the second chip, the third track being separated from the first chip by insulating material.

According to an embodiment, the third winding comprises a second conductive track in a third layer of the interconnection network of the second chip, the second track being separated from the first chip only by insulating material.

According to an embodiment, the second winding comprises a third conductive track in a fourth layer of the interconnection network of the first chip, the third track being separated from the first track by insulating material, the third track being located between the first track and the substrate of the first chip.

According to an embodiment, the second winding comprises a third conductive track in a fifth layer of the interconnection network of the second chip, the third track being separated from the first chip by insulating material.

According to an embodiment, the second and third tracks are located in the same third layer of the interconnection network of the second chip.

According to an embodiment, the device is configured to operate in time division duplex or frequency division duplex mode.

According to an embodiment, the molecular bonding is a metal-to-metal bonding or an oxide-to-oxide bonding.

Another embodiment provides a method of manufacturing a device adapted to transmitting and receiving signals with a same antenna, the device comprising first, second, and third windings, the first and second windings being coupled to transmit the signals to be transmitted by the antenna, the first and third windings being coupled to transmit the signals received by the antenna, the method comprising the forming of first and second chips, the first chip comprising the antenna and the first winding, and the second chip comprising a winding from among the second and third windings, the method further comprising the bonding of the first and second chips to each other by molecular bonding.

According to an embodiment, the previously-described manufacturing method is applied to the manufacturing of a device such as previously described.

### BRIEF DESCRIPTION OF THE DRAWINGS

The foregoing features and advantages, as well as others, will become apparent upon examining the detailed description of illustrative embodiments given for the purpose of illustration, without limitation, with reference to the accompanying drawings, in which:

FIG. 1 illustrates an example of a transceiver device;

FIG. 2 schematically illustrates an embodiment of a transceiver device;

FIG. 3 schematically illustrates the implementation of the embodiment of FIG. 2;

FIG. 4 schematically illustrates another embodiment of a transceiver device; and

FIG. 5 schematically illustrates the implementation of the embodiment of FIG. 4.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail. In particular, unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, or plus or minus 5%.

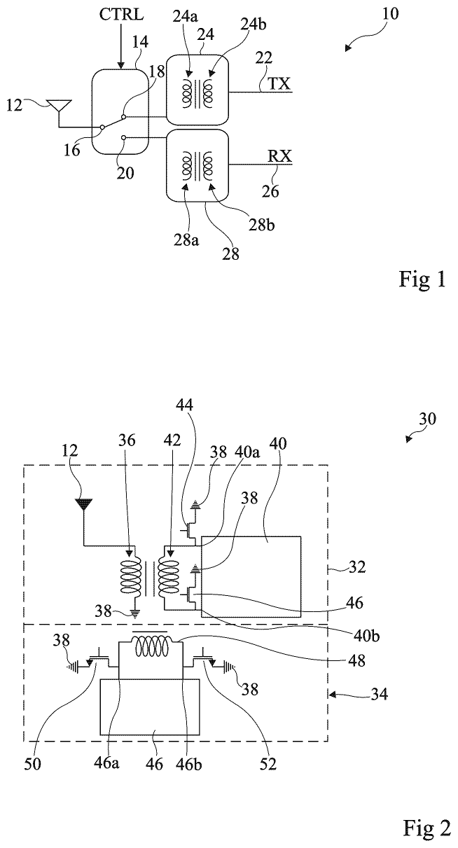

FIG. 1 illustrates an example of a transceiver device 10. Device 10 is for example configured to operate in frequency division duplex mode or in time division duplex mode.

Device 10 for example forms part of a transceiver system. Said system comprises device 10 and another transceiver device, not shown. The other device is configured to transmit and receive signals. The other device is configured to operate in the same operating mode as device 10. Device 10 and the other device are configured to be able to communicate in wireless fashion with each other.

Device 10 comprises an antenna 12, for example a single antenna 12. Antenna 12 is configured to transmit and receive signals.

Device 10 comprises for example a switching circuit 14. Circuit 14 comprises for example a main terminal 16 and two secondary terminals 18, 20. Circuit 14 is configured to connect terminal 16 to one or the other of terminals 18, 20. Circuit 14 is controlled by a control signal CTRL, for example a binary signal. Signal CTRL determines whether terminal 16 is coupled to terminal 18 or to terminal 14. Signal CTRL determines whether device 10 is in a transmit mode, that is, a mode where a signal is supplied to the antenna to be transmitted, or in a receive mode, where a signal is received by the antenna and is supplied by the antenna to the rest of device 10. Thus, signal CTRL may take a first value indicating that the device is in transmit mode and that circuit 14 couples terminals 16 and 18 or a second value indicating that the device is in receive mode and that circuit 14 couples terminals 16 and 20.

Switching circuit 14, and more precisely terminal 16, is coupled or connected, to antenna 12. Switching circuit 14, and more precisely terminal 18, is coupled or connected, to a node 22 having a signal TX to be transmitted supplied thereon, by a balun 24. Switching circuit 14, and more precisely terminal 20, is coupled or connected, to a node 26 having a signal RX received by antenna 12 obtained thereon, by a balun 28.

Balun 24 comprises two windings, or coils, a first winding 24a and a second winding 24b. One end of winding 24a is coupled or connected, to terminal 18. One end of winding 24b is coupled or connected, to node 22. Windings 24a and 24b are magnetically coupled to allow the transmission between antenna 12 and the rest of device 10. Similarly, balun 28 comprises two windings, a first winding 28a and a second winding 28b. One end of winding 28a is coupled or connected, to terminal 20. One end of winding 28b is coupled or connected, to node 26. Windings 28a and 28b are magnetically coupled to allow the transmission between antenna 12 and the rest of device 10.

There exists a need to ensure the separation between the transmission branch, comprising terminal 18, circuit, or balun, 24, and node 22, and the reception branch, comprising terminal 20, circuit, or balun, 28, and node 26, to avoid power leakages which might increase the power consumption and disturb transmissions.

FIG. 2 schematically shows an embodiment of a transceiver device 30. Device 30 is configured to operate in frequency division duplex mode or in time division duplex mode. Device 30 comprises elements of the device 10 of FIG. 1.

Device 30 comprises a first chip 32 and a second chip 34. Chip 32 comprises, and may comprise entirely, a transmission branch of device 30. Chip 34 comprises at least a portion of a reception branch of device 30.

Chip 32 comprises antenna 12. Chip 32 further comprises a winding 36. Winding 36 comprises an end coupled or connected, to antenna 12 and another end coupled or connected, to a reference node 38, for example the ground.

Chip 32 comprises a transmit circuit 40. Circuit 40 is configured to generate the signals to be transmitted by antenna 12.

Chip 32 further comprises a winding 42. The winding is coupled between two terminals 40a, 40b of circuit 40. Thus, winding 40 comprises a first end coupled or connected, to a terminal 40a of circuit 40 and a second end coupled or connected, to another terminal 40b of circuit 40.

Windings 36 and 42 are magnetically coupled so as to form balun 24. Winding 36 then corresponds to winding 24a and winding 42 corresponds to winding 24b. Windings 36 and 42 are configured to be coupled to each other so as to allow the transmission of signals in a first frequency range, corresponding to the transmission frequencies.

The terminals 40a and 40b of circuit 40 are for example each coupled to node 38 by a switch, for example a transistor. Thus, terminal 40a is for example coupled or connected, to a conduction terminal of a transistor 44, the other conduction terminal of transistor 44 being coupled or connected, to node 38. Terminal 40a is for example coupled or connected, to a conduction terminal of a transistor 46, the other conduction terminal of transistor 46 being coupled or connected, to node 38. Transistors 44 and 46 are for example controlled by a control circuit of device 30, for example located in chip 32.

Chip 34 comprises a receive circuit 46. Circuit 40 is configured to process the signals received by antenna 12.

Chip 34 further comprises a winding 48. Winding 48 is coupled between two terminals 46a, 46b of circuit 46. Thus, winding 48 comprises a first end coupled or connected, to a terminal 46a of circuit 46 and a second end coupled or connected, to another terminal 46b of circuit 46.

Windings 36 and 48 are magnetically coupled so as to form balun 28. Winding 36 then corresponds to winding 28a and winding 48 corresponds to winding 28b. Windings 36 and 48 are configured to be coupled to each other so as to allow the transmission of signals in a second frequency range, corresponding to the reception frequencies.

The terminals 46a and 46b of circuit 40 are for example each coupled to node 38 by a switch, for example a transistor. Thus, terminal 46a is for example coupled or connected, to a conduction terminal of a transistor 50, the other conduction terminal of transistor 50 being coupled or connected, to node 38. Terminal 46a is for example coupled or connected, to a conduction terminal of a transistor 52, the other conduction terminal of transistor 52 being coupled or connected, to node 38. Transistors 50 and 52 are for example controlled by a control circuit of device 30, for example located in chip 34.

Switches 44, 46, 50, 52 are for example configured to enable device 30 to operate in time division duplex mode.

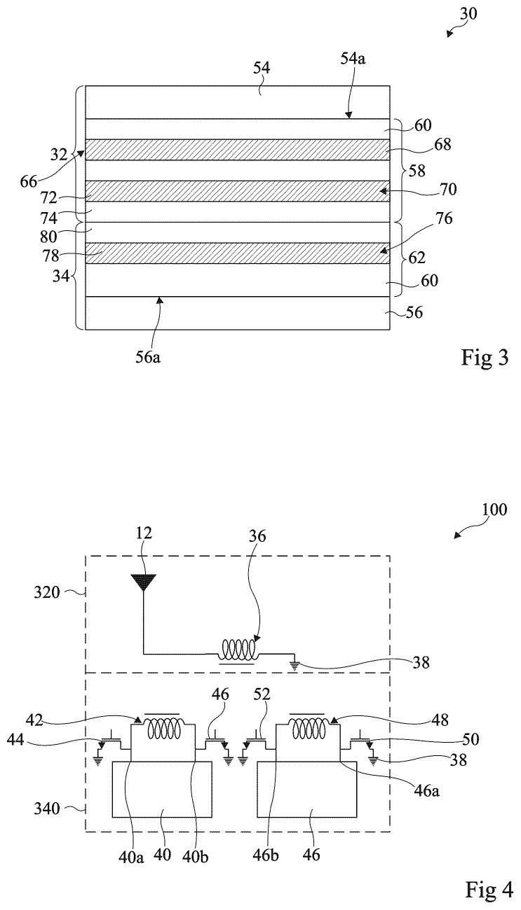

FIG. 3 schematically shows the implementation of the embodiment of FIG. 2.

Device 30 comprises, in FIG. 3, chip 32 and chip 34. Each chip 32, 34 comprises a substrate, for example a semiconductor substrate, where electronic components, for example forming circuits 40 and 46, may be formed. Chip 32 comprises a substrate 54 and chip 34 comprises a substrate 56. In other words, substrate 54 may comprise the electronic components of circuit 40, such as all the electronic components of circuit 40. Substrate 56 may comprise the electronic components of circuit 46, such as all the electronic components of circuit 46.

Further, each chip 32, 34 comprises an interconnection network covering its substrate 54 or 56.

Thus, chip 32 comprises an interconnection network 58. Network 58 comprises a stack of a plurality of insulating layers 60. More precisely, network 58 comprises an alternation of layers 60 comprising metal tracks, or metallizations, 68 and of layers 60 comprising des conductive vias coupling the metal tracks together. Network 58 rests on a surface 54a of substrate 54, for example over the entire surface 54a of substrate 54.

Similarly, chip 34 comprises an interconnection network 62. Network 62 comprises a stack of a plurality of insulating layers 60. More precisely, network 62 comprises an alternation of layers 60 comprising metal tracks, or metallizations, 78 and of layers 60 comprising conductive vias coupling the metal tracks together. Network 62 rests on a surface 56a of substrate 56, for example over the entire surface 56a of substrate 56.

Network 58 comprises a layer 66. Layer 66 is an insulating layer corresponding to a layer 60 of network 58, comprising a metallization 68. Layer 66 is separated from substrate 54 by at least one layer 60.

A metal track 68 is located in layer 66. Track 68 extends from an upper surface of layer 66, that is, the surface in contact with the top layer 60 in network 58, to a lower surface of layer 66, that is, the surface in contact with the bottom layer 60 in network 58. Metal track 68 forms the winding 42 of FIG. 2. Thus, the length of track 68 and its arrangement enable to form winding 42. For example, track 68 forms a spiral in layer 66, a first end of track 68 being located outside of the spiral and another end of track 68 being located inside of the spiral.

Network 58 comprises a layer 70. Layer 70 is an insulating layer corresponding to a layer 60 of network 58, comprising a metallization 78.

A metal track 72 is located in layer 70. Track 72 extends from an upper surface of layer 70, that is, the surface in contact with the top layer 60 in network 58, to a lower surface of layer 70, that is, the surface in contact with the bottom layer 60 in network 58. Metal track 72 forms the winding 36 of FIG. 2. Thus, the length of track 72 and its layout enable to form winding 36. For example, track 72 forms a spiral in layer 70, a first end of track 72 being located outside of the spiral and another end of track 72 being located inside of the spiral.

Track 72 is at least partially located in front of track 68. Layers 66 and 70, and more precisely tracks 68 and 72, are separated from each other by at least one layer 60. In some embodiments, the at least one layer 60 separating layers 66 and 70 comprises no metal tracks or conductive vias between tracks 68 and 72 or between the portions of layers 66 and 70 located between the portions of tracks 68 and 72.

The number and the height of the layers 60 separating layers 66 and 70 is selected to ensure that tracks 68 and 72, forming windings 36 and 42, are magnetically coupled and form a balun having the desired operating frequency range. For example, layers 66 and 70 are separated by a single layer 74 and a single layer 80. For example, layer 74 has a thickness in the range from 1 nm to 1 mm and layer 80 has a thickness in the range from 1 nm to 1 mm.

Network 58 comprises a layer 74. Layer 74 is an insulating layer covering layer 70. Layer 74 corresponds to the layer 60 most distant the substrate 54 of network 58. Layer 74 covers at least track 72, and in some embodiments entirely covers layer 70. Layer 74 for example corresponds to a single layer of the interconnection network or to a single layer made of an insulating material different from the material of layers 60. As a variant, layer 74 comprises a plurality of insulating layers, for example comprising one or a plurality of layers 60 and/or one or a plurality of insulating layers made of one or a plurality of insulating materials different from the material of layers 60.

Layer 74 is separated from layer 66 by layer 70. Layer 66 is located between layer 70 and substrate 54. Thus, network 58 in some embodiments comprises, in this order from surface 54a of substrate 54, one or a plurality of layers 60 separating layer 66 from substrate 54, layer 66, one or a plurality of layers 60 separating layers 66 and 70, layer 70, and layer 74.

The layer(s) 60 separating layer 66 from substrate 54 for example comprise conductive tracks and conductive vias, not shown, so as to electrically couple track 68 and substrate 54. More precisely, the layer(s) 60 separating layer 66 from substrate 54 for example comprise conductive tracks and conductive vias, not shown, so as to electrically couple track 68 and circuit 40.

The network 62 of chip 34 comprises a layer 76. Layer 76 is an insulating layer corresponding to a layer 60 in network 62. Layer 76 is in some embodiments separated from substrate 56 by at least one layer 60.

A metal track 78 is located in layer 76. Track 78 extends from an upper surface of layer 76, that is, the surface in contact with the top layer 60 in network 62, to a lower surface of layer 76 that is, the surface in contact with the bottom layer 60 in network 62. Metal track 78 forms the winding 48 of FIG. 2. Thus, the length of track 78 and its layout enable to form winding 48. For example, track 78 forms a spiral in layer 76, a first end of track 78 being located outside of the spiral and another end of track 78 being located inside of the spiral.

Network 62 comprises a layer 80. Layer 80 is an insulating layer covering layer 76. Layer 80 corresponds to the layer 60 most distant from the substrate 56 in network 62. Layer 80 covers at least track 78, and in some embodiments entirely covers layer 76. Layer 80 for example corresponds to a single layer of the interconnection network or to a single layer made of an insulating material different from the material of layers 60. Alternatively, layer 80 comprises a plurality of insulating layers, comprising for example one or a plurality of layers 60 and/or one or a plurality of insulating layers made of one or a plurality of insulating materials different from the material of layers 60.

Track 78 is for example separated from substrate 56 by at least one layer 60. Layer 80 is separated from substrate 56 by layer 76. Thus, network 62 comprises, in some embodiments, in this order from surface 56a of substrate 56, one or a plurality of layers 60 separating layer 76 from substrate 56, layer 76, and layer 80.

Track 78 is located at least partially in front of track 72. Layers 74 and 80 in some embodiments comprise no conductive elements between tracks 72 and 78 and between the portions of layers 70 and 76 located in the spiral formed by track 72 or 78.

Tracks 78 and 72 are arranged so as to be magnetically coupled and form a balun having the desired operating frequency range. Thus, layers 74 and 80, and more particularly the thickness of layers 74 and 80, are selected so as to ensure that tracks 72 and 78 are magnetically coupled and form the balun. For example, layer 74 has a thickness in the range from 1 nm to 1 mm and layer 80 has a thickness in the range from 1 nm to 1 mm.

The layer(s) 60 separating layer 78 from substrate 56 for example comprise conductive tracks and conductive vias, not shown, so as to electrically couple track 78 and substrate 56. More precisely, the layer(s) 60 separating layer 78 from substrate 56 for example comprise conductive tracks and conductive vias, not shown, so as to electrically couple track 78 and circuit 46.

Chips 32 and 34 are bonded to each other by molecular bonding, in some embodiments of hybrid type, such as metal-to-metal bonding, oxide-to-oxide bonding, or a combination thereof. More precisely, layers 74 and 80 are bonded to each other by molecular bonding. Thus, the surface of layer 74 most distant from substrate 54 is in contact with the surface of layer 80 most distant from substrate 56.

Layers 74 and 80 for example comprise conductive tracks, not shown, in contact with one another to allow the electric coupling of chips 32 and 34. Said tracks, not shown, are not located between tracks 72 and 78.

FIG. 4 schematically shows another embodiment of a transceiver device 100.

Device 100 comprises the elements, in some embodiments all the elements, of device 30, arranged differently.

Thus, a chip 320 comprises, like the chip 32 of FIG. 2, antenna 12 and winding 36. As in FIG. 2, one end of winding 36 is coupled or connected, to antenna 12 and the other end of winding 36 is coupled or connected, to node 38.

A chip 340 comprises, like the chip 34 of FIG. 2, winding 48, circuit 46, and transistors 50, 52. As in FIG. 2, winding 48 is coupled or connected, between the terminals 46a and 46b of circuit 46 and transistors 50, 52 are coupled as in FIG. 2.

Conversely to the embodiment of FIG. 2, chip 340 also comprises circuit 40, winding 42, and transistors 44, 46. As in FIG. 2, winding 42 is coupled or connected, between the terminals 40a and 40b of circuit 40 and transistors 44, 46 are coupled as in FIG. 2.

Windings 36, 42, 48 are arranged in such a way that windings 36 and 42 are coupled, in such a way that windings 36 and 48 are coupled, and in such a way that windings 42 and 48 are neither coupled nor in contact. Windings 36 and 42 are coupled so as to only transmit the transmission operating frequency range. Windings 36 and 48 are coupled to only transmit the reception operating frequency range.

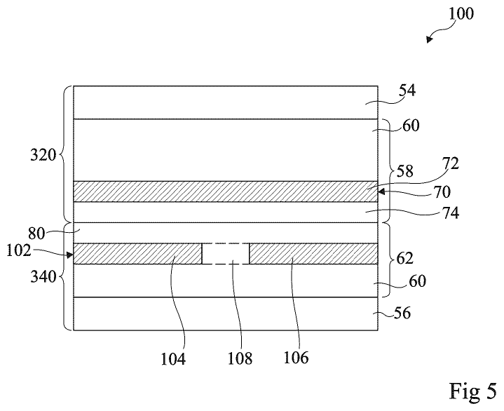

FIG. 5 schematically shows the implementation of the embodiment of FIG. 4.

Device 100 comprises, in FIG. 5, chip 320 and chip 340. Each chip 320, 340 comprises a substrate, for example a semiconductor substrate, inside of which electronic components may be formed. More precisely, chip 320 comprises, like the chip 32 of FIG. 3, substrate 54, and chip 340 comprises substrate 36. Conversely to the embodiment of FIG. 3, substrate 56 comprises the electronic components of circuits 40 and 46, in some embodiments all the components of circuits 40 and 46. Substrate 54 in some embodiments comprises no electronic components of circuits 40 and 46.

Further, each chip 320, 340 comprises the interconnection network covering its substrate 54 or 56.

Thus, like the chip 32 of FIG. 3, chip 320 comprises interconnection network 58. Network 58 comprises a stack of a plurality of insulating layers 60. More precisely, network 58 comprises an alternation of layers 60 comprising metal tracks, or metallizations, and of layers 60 comprising conductive vias coupling the metal tracks together. Network 58 rests on surface 54a of substrate 54, for example over the entire surface 54a of substrate 54.

Similarly, chip 340 comprises an interconnection network 62. Network 62 comprises a stack of a plurality of insulating layers 60. More precisely, network 62 comprises an alternation of layers 60 comprising metal tracks, or metallizations, and of layers 60 comprising conductive vias coupling the metal tracks together. Network 62 rests on surface 56a of substrate 56, for example over the entire surface 56a of substrate 56.

Network 58 comprises layer 70. Layer 70 is, as in FIG. 3, an insulating layer corresponding to a layer 60 of network 58.

Metal track 72 is located in layer 70. Track 72 extends, as in FIG. 3, from an upper surface of layer 70, that is, the surface in contact with the top layer 60 in network 58, to a lower surface of layer 70, that is, the surface in contact with the bottom layer 60 in network 58. Metal track 72 forms the winding 36 of FIG. 4. Thus, the length of track 72 and its layout enable to form winding 36. For example, track 72 forms a spiral in layer 70, a first end of track 72 being located outside of the spiral and another end of track 72 being located inside of the spiral.

Conversely to the device 30 of FIG. 3, chip 320 does not comprise layer 66 and does not comprise track 68.

Network 58 comprises layer 74, as in FIG. 3, corresponding to a layer 60. Layer 74 is an insulating layer covering layer 70. Layer 74 corresponds to the layer 60 most distant from substrate 54 of network 58. Layer 74 covers at least track 72, and in some embodiments entirely covers layer 70.

Network 58 in some embodiments comprises, in this order from surface 54a of substrate 54, one or a plurality of layers 60 separating layer 70 from substrate 54, layer 70, and layer 74.

The layer(s) 60 separating layer 70 from substrate 54 for example comprise conductive tracks and conductive vias, not shown, so as to electrically couple track 72 and substrate 54.

Conversely to the embodiment of FIG. 3, the network 62 of chip 340 does not comprise layer 76. The network 62 of chip 340 comprises a layer 102. Layer 102 is an insulating layer corresponding to a layer 60 in network 62. Layer 102 is in some embodiments separated from substrate 56 by at least one layer 60.

A metal track 104 is located in layer 102. Track 104 extends from an upper surface of layer 100, that is, the surface in contact with the top layer 60 in network 62, to a lower surface of layer 102 that is, the surface in contact with the bottom layer 60 in network 62. Metal track 104 forms the winding 42 of FIG. 4. Thus, the length of track 104 and its layout enable to form winding 42. For example, track 104 forms a spiral in layer 102, a first end of the track 104 being located outside of the spiral and another end of track 104 being located inside of the spiral.

Another metal track 106 is located in layer 102. Track 106 extends from an upper surface of layer 100, that is, the surface in contact with the top layer 60 in network 62, to a lower surface of layer 102 that is, the surface in contact with the bottom layer 60 in network 62. Metal track 106 forms the winding 48 of FIG. 4. Thus, the length of the track 106 and its layout enable to form winding 48. For example, track 106 forms a spiral in layer 102, a first end of track 106 being located outside of the spiral and another end of track 106 being located inside of the spiral.

Tracks 102 and 104 are not in contact. Thus, tracks 102 and 104 are separated by a portion 108 of layer 102.

Alternatively, tracks 104 and 106 may be located in separate layers in network 62. Tracks 104 and 106 are arranged so as not to face each other, even partially. Each track 104, 106 is separated from chip 320, and more particularly from track 72, only by electrically-insulating materials, for example by layers 60, 80, 74.

Network 62 comprises a layer 80, corresponding to a layer 60. Layer 80 is an insulating layer covering layer 102. Layer 80 corresponds to the layer 60 most distant from substrate 56 in network 62. Layer 80 covers at least tracks 104 and 106, and in some embodiments entirely covers layer 102.

Tracks 104 and 106 are for example separated from substrate 56 by at least one layer 60. Layer 80 is separated from substrate 56 by layer 102. Thus, network 62 comprises, in some embodiments, in this order from surface 56a of substrate 56, one or a plurality of layers 60 separating layer 102 from substrate 56, layer 102, and layer 80.

Tracks 104 and 106 are at least partially located in front of track 72. More precisely, track 104 is located at least partially in front of track 72 and track 106 is located at least partially in front of track 72. Layers 74 and 80 in some embodiments comprise no conductive elements between tracks 104 and 72, between tracks 106 and 72, and between the portions of layers 70 and 102 located in the spirals formed by track 72, 104, or 106.

Tracks 104 and 72 are arranged so as to be magnetically coupled and form a balun having the desired operating frequency range to allow the transmission by antenna 12. Thus, layers 74 and 80, and more particularly the thickness of layers 74 and 80, are selected to ensure that tracks 72 and 104 are magnetically coupled and form the balun.

Tracks 106 and 72 are arranged so as to be magnetically coupled and form a balun having the desired operating frequency range to allow the reception by antenna 12. Thus, layers 74 and 80, and more particularly the thickness of layers 74 and 80, are selected to ensure that tracks 72 and 106 are magnetically coupled and form the balun.

The layers 60 separating layer 102 from substrate 56 for example comprise conductive tracks and conductive vias, not shown, so as to electrically couple track 104 and substrate 56 and for example comprise conductive tracks and conductive vias, not shown, to electrically couple track 103 and substrate 56. Tracks 104 and 106 are in some embodiments not electrically connected by conductive vias or tracks located in the layers 60 of network 62.

As in FIG. 3, chips 320 and 340 are bonded to each other by molecular bonding, in some embodiments of hybrid type. More precisely, layers 74 and 80 are bonded to each other by molecular bonding. Thus, the surface of layer 74 most distant from substrate 54 is in contact with the surface of layer 80 most distant from substrate 56.

Layers 74 and 80 for example comprise conductive tracks, not shown, in contact with one another so as to allow the electric coupling of chips 320 and 340. Said tracks, not shown, are not located between tracks 72 and 104 or between tracks 72 and 106.

An advantage of the described embodiments is the decrease in power leakages between the transmission and reception paths. Indeed, in the described embodiments, windings 42 and 48 are not electrically coupled by conductive elements, for example vias.

Another advantage of the described embodiments is that the absence of a physical connection between circuits 40 and 46 enables to form a protection against electrostatic discharges.

Various embodiments and variants have been described. Those skilled in the art will understand that certain features of these various embodiments and variants may be combined, and other variants will occur to those skilled in the art. In particular, in the embodiment of FIGS. 2 and 3, the assembly comprising circuit 40, winding 42, and transistors 44, 46 and the assembly comprising circuit 46, winding 48, and transistors 50, 52 may be exchanged.

Finally, the practical implementation of the described embodiments and variants is within the abilities of those skilled in the art based on the functional indications given hereabove.

What is claimed is:

1. A device for transmitting and receiving signals, the device being configured to transmit and receive the signals with a same antenna, the device comprising:
first, second, and third windings, the first and second windings being coupled in order to transmit the signals to be transmitted by the antenna, the first and third windings being coupled in order to transmit the signals received by the antenna; and
first and second chips, the first chip comprising the antenna and the first winding, and the second chip comprising a winding from among the second and third windings, the first and second chips being bonded to each other by molecular bonding.

2. The device according to claim 1, wherein the first winding is coupled between the antenna and a node of application of a reference voltage, the second winding is coupled between two terminals of a first circuit configured to generate a signal to be transmitted, and the third winding is coupled between two terminals of a second circuit configured to process a received signal.

3. The device according to claim 1, wherein each first or second chip comprises a semiconductor substrate and an interconnection network comprising a stack of insulating layers comprising conductive tracks and conductive vias, each respective interconnection network comprising a first layer, the respective first layer of each respective interconnection network being most distant from the substrate of each chip, and wherein the first and second chips are bonded to each other by the first layers of each interconnection network.

4. The device according to claim 3, wherein the first winding comprises a first conductive track in a second layer of the interconnection network of the first chip, the first conductive track being separated from the second chip only by insulating material.

5. The device according to claim 4, wherein the second winding comprises a second conductive track in a third layer of the interconnection network of the second chip, the second conductive track being separated from the first chip only by insulating material.

6. The device according to claim 5, wherein the third winding comprises a third conductive track in a fourth layer of the interconnection network of the first chip, the third conductive track being separated from the first conductive track by insulating material, the third conductive track being located between the first conductive track and the substrate of the first chip.

7. The device according to claim 5, wherein the third winding comprises a third conductive track in a fifth layer of the interconnection network of the second chip, the third conductive track being separated from the first chip by insulating material.

8. The device according to claim 7, wherein the second and third conductive tracks are located in the same third layer of the interconnection network of the second chip.

9. The device according to claim 4, wherein the third winding comprises a second conductive track in a third layer of the interconnection network of the second chip, the second conductive track being separated from the first chip only by insulating material.

10. The device according to claim 9, wherein the second winding comprises a third conductive track in a fourth layer of the interconnection network of the first chip, the third conductive track being separated from the first conductive track by insulating material, the third conductive track being located between the first conductive track and the substrate of the first chip.

11. The device according to claim 9, wherein the second winding comprises a third conductive track in a fifth layer of the interconnection network of the second chip, the third conductive track being separated from the first chip by insulating material.

12. The device according to claim 11, wherein the second and third conductive tracks are located in the same third layer of the interconnection network of the second chip.

13. The device according to claim 1, wherein the device is configured to operate in time division duplex mode or by frequency division duplex.

14. The device according to claim 1, wherein the molecular bonding is a metal-to-metal bonding or an oxide-to-oxide bonding.

15. A device for transmitting and receiving signals, the device comprising:
an antenna;
a first interconnection network coupled to the antenna, the first interconnection network comprising a first insulating layer covering a first metallization, the first metallization comprising a first winding and a second winding, the second winding being coupled with the first winding to transmit a signal to be transmitted by the antenna; and
a second interconnection network coupled to the antenna, the second interconnection network comprising a second insulating layer bonded to the first insulating layer, the second insulating layer covering a second metallization, the second metallization comprising a third winding, the third winding being coupled with the first winding to transmit a signal received by the antenna.

16. The device according to claim 15, wherein the second insulating layer is bonded to the first insulating layer with molecular bonding.

17. The device according to claim 16, wherein the molecular bonding is a metal-to-metal bonding or an oxide-to-oxide bonding.

18. A method of manufacturing a device configured for transmitting and receiving signals with a same antenna, the method comprising:
forming a first chip, a second chip, a first winding, a second winding, and a third winding, the first chip comprising an antenna and the first winding, the second chip comprising a winding from among the second and third windings, the first and second windings being coupled so as to transmit the signals to be transmitted by the antenna, the first and third windings being coupled so as to transmit the signals received by the antenna; and
bonding the first and second chips to each other with molecular bonding.

19. The method according to claim 18, wherein the second winding is part of the first chip and the third winding is part of the second chip.

20. The method according to claim 18, wherein the second winding and the third winding are part of the second chip.
